(19) United States
(12) Patent Application Publication
(10) Pub. No.: US 2023/0051822 A1
(43) Pub. Date: Feb. 16, 2023

(54) FILM FORMING APPARATUS

(71) Applicant: Tokyo Electron Limited, Tokyo (JP)

(72) Inventor: Tatsuya YAMAGUCHI, Nirasaki City (JP)

(21) Appl. No.: 17/818,547

(22) Filed: Aug. 9, 2022

(30) Foreign Application Priority Data
Aug. 10, 2021 (JP) 2021-130911

(51) Int. Cl. C23C 16/44; C23C 16/458; C23C 16/455

(52) U.S. Cl. CPC C23C 16/4412; C23C 16/4405; C23C 16/4585; C23C 16/45565

(57) ABSTRACT

A film forming apparatus includes a stage on which a substrate is mounted, a first container configured to accommodate the stage, a gas supply configured to supply gases containing two types of monomers into the first container to form a polymer film on the substrate mounted on the stage, a porous member arranged radially outward from a processing space, which is a space above the substrate, and configured to draw in polymers formed by the gases containing two types of monomers exhausted from the first container, and a heater configured to heat the porous member to a first temperature when the polymer film is formed on the substrate.

### CROSS-REFERENCE TO RELATED APPLICATION

This application is based upon and claims the benefit of priority from Japanese Patent Application No. 2021-130911, filed on Aug. 10, 2021, the entire contents of which are incorporated herein by reference.

### TECHNICAL FIELD

The present disclosure relates to a film forming apparatus.

### BACKGROUND

In the related art, there is known a technique in which a polymer having a urea bond is embedded in a void formed in a substrate, an oxide film is formed on the substrate, and then the polymer is depolymerized. The depolymerized polymer is desorbed via an oxide film to form a void in the lower layer of the oxide film.

### PRIOR ART DOCUMENT

### [Patent Document]

### Patent Document 1:

Japanese Patent Application Publication No. 2019-207909

### SUMMARY

According to one embodiment of the present disclosure, there is provided a film forming apparatus including a stage on which a substrate is mounted, a first container configured to accommodate the stage, a gas supply configured to supply gases containing two types of monomers into the first container to form a polymer film on the substrate mounted on the stage, a porous member arranged radially outward from a processing space, which is a space above the substrate, and configured to draw in polymers formed by the gases containing two types of monomers exhausted from the first container, and a heater configured to heat the porous member to a first temperature when the polymer film is formed on the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of a film forming apparatus according to a first embodiment.

FIG. 2 is a diagram showing an example of the absorption amounts of polymers by porous members having different surface areas.

FIG. 3 is a diagram showing an example of the absorption amounts of polymers by porous members having different surface areas.

FIG. 4 is a diagram showing an example of the relationship between the temperature of a member and the deposition rate (D/R) of the polymers stacked on the member.

FIG. 5 is a diagram showing an example of the relationship between the temperature of a member and the cleaning rate of the polymers stacked on the member.

FIG. 6 is a flowchart showing an example of a film forming method.

FIG. 7 is a flowchart showing another example of the film forming method.

FIG. 8 is a schematic sectional view showing an example of a film forming apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the disclosed film forming apparatus will be described in detail with reference to the drawings. It should be noted that the following embodiments do not limit the disclosed film forming apparatus.

By the way, not all the monomers contained in the gas supplied into the processing container contribute to a reaction. Therefore, the monomers that did not contribute to the reaction are exhausted from the inside of the processing container. However, in the process of exhaust, a polymerization reaction may occur between the monomers, and an organic film (hereinafter referred to as a deposit) may be formed in an exhaust path. If the deposit is formed on a pressure regulation valve, an exhaust pump, or the like provided in the exhaust path, it becomes difficult to maintain the inside of the processing container at a predetermined pressure.

Therefore, in order to prevent the polymerization reaction from occurring in the exhaust path, it is conceivable to heat the entire exhaust path. However, the heating of the entire exhaust path leads to an increase in the size of the apparatus and an increase in power consumption due to the arrangement of heating members. Further, when the unreacted monomers contained in the exhaust gas are drawn in in the form of polymers by using a trap arranged in the exhaust path, it is necessary to periodically remove the polymers generated in the trap. Therefore, the exhaust mechanism is stopped periodically, and the downtime of the film forming apparatus becomes long.

Therefore, the present disclosure provides a technique capable of preventing a deposit from adhering to an exhaust path.

### First Embodiment

### [Configuration of Film Forming Apparatus 10]

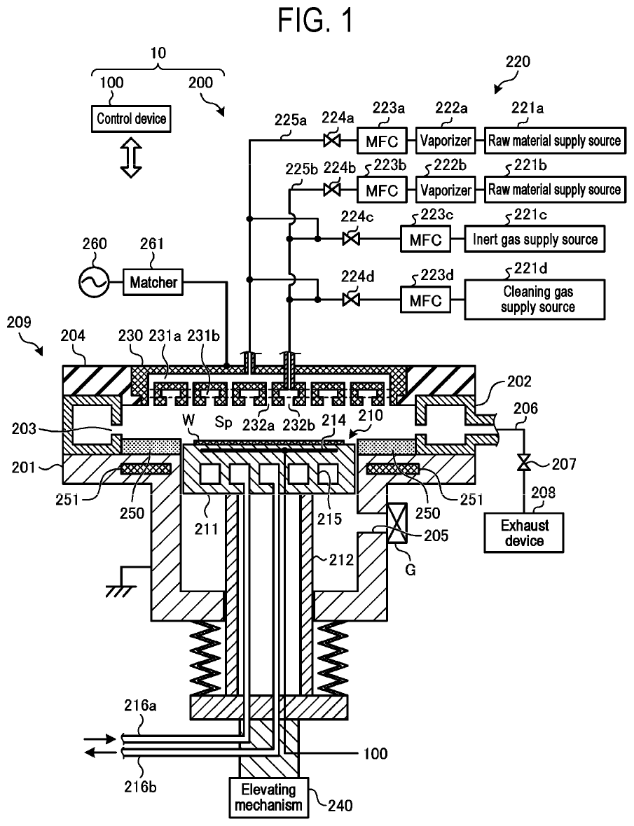

FIG. 1 is a schematic sectional view showing an example of a film forming apparatus 10 according to a first embodiment. The film forming apparatus 10 includes an apparatus main body 200 and a control device 100 that controls the apparatus main body 200. The apparatus main body 200 includes a processing container 209. The processing container 209 includes a lower container 201, an exhaust duct 202, a support structure 210, and a shower head 230. The processing container 209 is an example of a first container.

The lower container 201 is made of a metal such as aluminum or the like. The exhaust duct 202 is provided on the upper peripheral edge of the lower container 201. Further, an annular insulating member 204 is arranged on the exhaust duct 202. The shower head 230 is provided above the lower container 201 and is supported by the insulating member 204. The support structure 210 on which a substrate W is mounted is provided substantially at the center of the lower container 201. In the following, the space in the processing container 209 surrounded by the lower container 201, the exhaust duct 202, the support structure 210, and the shower head 230 is defined as a processing space Sp.

An opening 205 for loading and unloading the substrate W is formed on the side wall of the lower container 201. The opening 205 is opened and closed by a gate valve G. The exhaust duct 202 has a square shape with a hollow vertical cross section, and extends in an annular shape along the upper peripheral edge of the lower container 201. The exhaust duct 202 has a slit-shaped exhaust port 203 formed along the extension direction of the exhaust duct 202. The exhaust port 203 is arranged outside the region of the substrate W along the peripheral edge of the substrate W mounted on the support structure 210, and is configured to exhaust the gas in the processing space Sp.

One end of an exhaust pipe 206 is connected to the exhaust duct 202. The other end of the exhaust pipe 206 is connected to an exhaust device 208 including a vacuum pump or the like via a pressure regulation valve 207 such as an APC (Auto Pressure Controller) valve or the like. The pressure regulation valve 207 is controlled by the control device 100 to control the pressure in the processing space Sp to a preset pressure.

A porous member 250 is provided in the processing space Sp. In the present embodiment, the porous member 250 is arranged on the lower container 201 between the support structure 210 and the exhaust duct 202 and arranged radially outward from the region of the support structure 210 in which the substrate W is arranged in the vertical direction. That is, the porous member 250 is arranged radially outward from the processing space Sp, which is a space above the substrate W mounted on the stage 211. The porous member 250 draws in the polymers formed by the gases containing two types of monomers exhausted from the inside of the processing container 209. As long as the porous member 250 is arranged outside the processing space Sp above the substrate W mounted on the support structure 210, the porous member 250 may be arranged on the lower surface of the insulating member 204 or on the side wall of the exhaust duct 202 on the side of the processing space Sp.

A heater 251 is embedded in the lower container 201 below the porous member 250. The heater 251 is controlled by the control device 100 to heat the porous member 250 to a predetermined temperature. The predetermined temperature is an example of a first temperature. In the present embodiment, the predetermined temperature is a temperature at which the adsorption time of monomers is in the range of, for example, 0.00001 ms or more and 0.01 ms or less. In the present embodiment, the predetermined temperature is, for example, a temperature in the range of 130 degrees C. to 170 degrees C. In the present embodiment, the monomers are, for example, isocyanates and amines.

Further, heaters (not shown) are also provided on the side wall of the exhaust duct 202 and the upper surface of the shower head 230. The exhaust duct 202 and the shower head 230 are heated to a temperature of, for example, 200 degrees C. or higher. This makes it possible to suppress the adhesion of a reaction by-product (so-called deposit) to the exhaust duct 202 and the shower head 230. The exhaust pipe 206, the pressure regulation valve 207, and the exhaust device 208 may also be provided with heaters and may be heated to a temperature at which the deposit is unlikely to adhere.

The support structure 210 includes a stage 211 and a support portion 212. The stage 211 is made of a metal such as aluminum or the like, and the substrate W is mounted on the upper surface thereof. The support portion 212 is made of a metal such as aluminum or the like and is formed in a cylindrical shape to support the stage 211 from below.

A heater 214 is embedded in the stage 211. The heater 214 heats the substrate W mounted on the stage 211 according to the supplied electric power. The electric power supplied to the heater 214 is controlled by the control device 100.

Further, a flow path 215 through which a refrigerant flows is formed in the stage 211. A chiller unit (not shown) is connected to the flow path 215 via a pipe 216a and a pipe 216b. The refrigerant whose temperature is adjusted to a predetermined temperature by the chiller unit is supplied to the flow path 215 via the pipe 216a. The refrigerant circulating through the flow path 215 is returned to the chiller unit via the pipe 216b. The stage 211 is cooled by the refrigerant circulating through the flow path 215. The chiller unit is controlled by the control device 100.

The support portion 212 is arranged in the lower container 201 so as to penetrate the opening formed at the bottom of the lower container 201. The support portion 212 is moved up and down by driving the elevating mechanism 240. When the substrate W is loaded, the support structure 210 is lowered by driving the elevating mechanism 240, and the gate valve G is opened. Then, the substrate W is loaded into the lower container 201 through the opening 205 and mounted on the stage 211. Then, the gate valve G is closed, the support structure 210 is raised by driving the elevating mechanism 240, and a film forming process on the substrate W is executed. Further, when the substrate W is unloaded, the support structure 210 is lowered by driving the elevating mechanism 240, and the gate valve G is opened. Then, the substrate W is unloaded from the stage 211 through the opening 205.

The shower head 230 includes a diffusion chamber 231a and a diffusion chamber 231b. The diffusion chamber 231a and the diffusion chamber 231b do not communicate with each other. A gas supply 220 is connected to the diffusion chamber 231a and the diffusion chamber 231b. Specifically, a valve 224a, an MFC (Mass Flow Controller) 223a, a vaporizer 222a, and a raw material supply source 221a are connected to the diffusion chamber 231a via a pipe 225a. The raw material supply source 221a is a source of isocyanate, which is an example of monomers. The vaporizer 222a vaporizes the isocyanate liquid supplied from the raw material supply source 221a. The MFC 223a controls the flow rate of the isocyanate vapor vaporized by the vaporizer 222a. The valve 224a controls the supply and stop of supply of isocyanate vapor to the pipe 225a.

A valve 224b, an MFC 223b, a vaporizer 222b, and a raw material supply source 221b are connected to the diffusion chamber 231b via a pipe 225b. The raw material supply source 221b is a source of amine, which is an example of monomers. The vaporizer 222b vaporizes the amine liquid supplied from the raw material supply source 221b. The MFC 223b controls the flow rate of the amine vapor vaporized by the vaporizer 222b. The valve 224b controls the supply and stop of supply of the amine vapor to the pipe 225b.

Further, a valve 224c, an MFC 223c, and an inert gas supply source 221c are connected to the shower head 230 via the pipe 225a and the pipe 225b. The inert gas supply source 221c is a source of an inert gas such as a rare gas or a nitrogen gas. The MFC 223c controls the flow rate of the inert gas supplied from the inert gas supply source 221c. The valve 224c controls the supply and stop of supply of the inert gas to the pipe 225a and the pipe 225b.

Further, a valve 224d, an MFC 223d, and a cleaning gas supply source 221d are connected to the shower head 230 via the pipe 225a and the pipe 225b. The cleaning gas supply source 221d is a source of a cleaning gas containing molecules containing, for example, oxygen atoms or fluorine atoms. The MFC 223d controls the flow rate of the cleaning gas supplied from the cleaning gas supply source 221d. The valve 224d controls the supply and stop of supply of the cleaning gas to the pipe 225a and the pipe 225b.

The diffusion chamber 231a communicates with the processing space Sp via a plurality of discharge ports 232a, and the diffusion chamber 231b communicates with the processing space Sp via a plurality of discharge ports 232b. The isocyanate vapor supplied into the diffusion chamber 231a via the pipe 225a is diffused in the diffusion chamber 231a and is discharged like a shower into the processing space Sp through the discharge ports 232a. Further, the amine vapor, the inert gas, and the cleaning gas supplied into the diffusion chamber 231b via the pipe 225b are diffused in the diffusion chamber 231b and are discharged like a shower into the processing space Sp via the discharge ports 232b. The isocyanate vapor and the amine vapor are discharged into the processing space Sp via the discharge ports 232a and the discharge ports 232b, and then mixed with each other in the processing space Sp to form a polymer film having urea bonds on the surface of the substrate W mounted on the stage 211.

An RF power source 260 for supplying RF (Radio Frequency) power for plasma generation is connected to the shower head 230 via a matcher 261. The shower head 230 functions as a cathode electrode with respect to the stage 211. In cleaning the processing space Sp, a cleaning gas is supplied from the gas supply 220 into the processing space Sp via the shower head 230, and RF power is supplied from the RF power source 260 into the processing space Sp via the matcher 261. As a result, the cleaning gas is turned into plasma in the processing space Sp, and the cleaning in the processing space Sp is performed by the active species contained in the plasma.

The control device 100 includes a memory, a processor, and an input/output interface. A control program, a processing recipe, and the like are stored in the memory. The processor reads a control program from the memory and executes the same. The processor controls each part of the apparatus main body 200 via the input/output interface based on the recipe or the like stored in the memory.

### [Structure of Porous Member 250]

The porous member 250 according to the present embodiment has a volume of about 500 cm³. A plurality of fine pores having an opening diameter of about 1 μm is formed in the porous member 250. The porous member 250 has a surface area of 50,000,000 cm² or more. In the present embodiment, the surface area of the porous member 250 is about 60,000,000 cm².

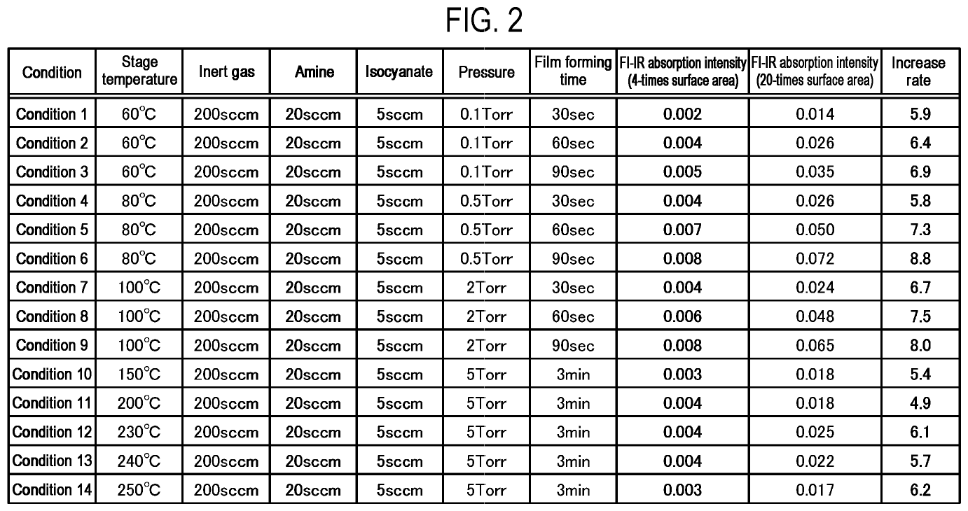

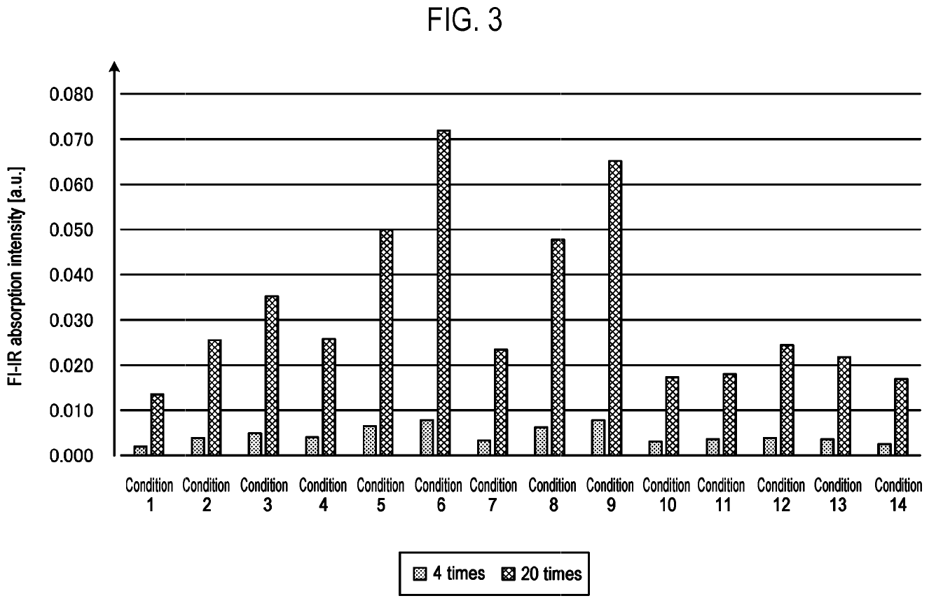

FIGS. 2 and 3 are views showing an example of the absorption amounts of polymers absorbed by the porous members 250 having different surface areas. In the example of FIGS. 2 and 3, there are shown the absorption amounts of the polymers absorbed by the porous member having a surface area 4 times as large as the surface area of a structure having a flat surface and the absorption amounts of the polymers absorbed by the porous member having a surface area 20 times as large as the surface area of a structure having a flat surface. On the surface of the porous member having the 4-times surface area, a large number of recesses having an opening diameter and depth of 40 nm to 150 nm are formed. Further, on the surface of the porous member having the 20-times surface area, a large number of recesses having an opening diameter and depth of 80 nm to 2000 nm are formed. In the example of FIGS. 2 and 3, the porous member to be tested was mounted on the stage 211, and the temperature was adjusted by the heater 214.

For example, as shown in FIGS. 2 and 3, in any temperature zone and pressure zone, the absorption amount of the polymers absorbed by the porous member having the 20-times surface area is about 5 times as large as the absorption amount of the polymers absorbed by the porous member having the 4-times surface area. Therefore, by increasing the surface area of the porous member, it is possible to increase the absorption amount of the polymers.

### [Polymer Deposition Rate]

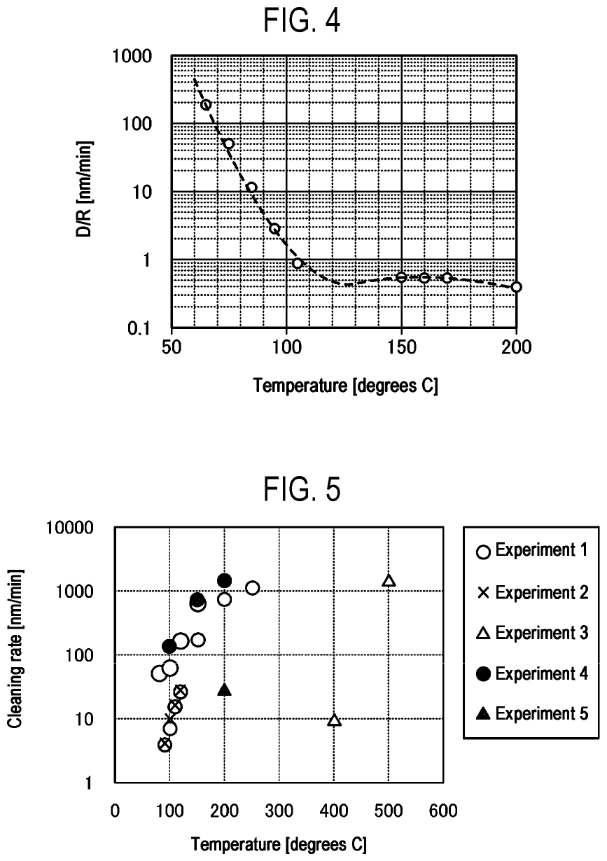

FIG. 4 is a diagram showing an example of the relationship between the temperature of the member and the deposition rate (D/R) of the polymers stacked on the member. For example, as shown in FIG. 4, as the temperature of the member decreases, the surface adsorption time of raw material molecules becomes longer, the probability of collision between the molecules increases, and the D/R increases. On the other hand, as the temperature of the member increases, the surface adsorption time becomes shorter, and the D/R is dominated by the probability of molecular collision on the surface of the member. That is, in the range where the temperature of the member is 130 degrees C. or higher, the adsorption time of the molecules is 0.01 ms or less, and the D/R does not depend on the temperature of the member but depends on the gas concentration. Further, in the range where the temperature of the member is 130 degrees C. or higher, the surface adsorption time of the molecules is sufficiently short. Therefore, the gas is diffused into the porous member, and a film is uniformly formed within the porous member by the gas.

If the temperature of the porous member 250 is low, the D/R of the polymers formed on the porous member 250 is high, so that the pores on the surface of the porous member 250 are closed by the polymers at an early stage. As a result, the polymers do not reach the pores inside the porous member 250, and consequently, it becomes difficult to draw a large amount of polymers into the porous member 250. Therefore, in the present embodiment, the porous member 250 is heated to a certain temperature to reduce the D/R of the polymers formed in the porous member 250. As a result, the pores on the surface of the porous member 250 are not blocked by the polymers, and the polymers reach the pores inside the porous member 250, whereby the polymers are drawn into the entire porous member 250. Therefore, it is possible to improve the polymer absorption capacity of the porous member 250 and to efficiently draw the polymers into the porous member 250.

However, if the temperature of the porous member 250 is too high, the polymerization reaction does not occur on the surface of the porous member 250, and the polymers are not drawn into the porous member 250. Therefore, the temperature of the porous member 250 is preferably set to a temperature within a temperature range in which the polymerization reaction occurs on the surface of the porous member 250 but the depolymerization reaction does not occur excessively.

Referring to FIG. 4, the D/R of the polymers decreases as the temperature increases. The decrease of the D/R becomes gentle at around 130 degrees C. Then, the D/R hardly changes up to around 170 degrees C., and the D/R decreases again around 200 degrees C. Therefore, in the present embodiment, the temperature of the porous member 250 is preferably 130 degrees C. to 170 degrees C. By doing so, the polymers can be efficiently drawn into the porous member 250.

[Removal of Polymer Drawn into Porous Member 250]

FIG. 5 is a diagram showing an example of the relationship between the temperature of the member and the cleaning rate of the polymers stacked on the member. As shown in FIG. 5, in Experiment 1, cleaning was performed using plasma generated by an oxygen gas. In Experiment 2, cleaning was performed using plasma generated by an NF₃ gas. Further, in Experiment 3, the member on which the polymers are stacked was exposed to an oxygen gas. In Experiment 4, the member on which the polymers are stacked was exposed to a fluorine gas. In Experiment 5, the member on which the polymers are stacked was exposed to an ozone gas. Plasma was not used in Experiments 3 to 5.

Referring to FIG. 5, in Experiments 1 and 2, a cleaning rate of 10 to 1000 nm/min was obtained in the temperature range of 100 degrees C. to 200 degrees C. for the member on which the polymers are stacked. Comparing Experiments 1 and 2, the plasma using the oxygen gas has a higher cleaning rate than the plasma using the NF₃ gas.

Further, in Experiment 3, the cleaning rate of the polymers was not obtained unless the temperature of the member on which the polymers are stacked is heated to 400 degrees C. or higher. On the other hand, in Experiments 4 and 5, a certain degree of cleaning rate was obtained even when the temperature of the member on which the polymers are stacked is about 100 degrees C. to 200 degrees C. Therefore, when plasma is not used, it is preferable to use a gas having higher reactivity than an oxygen gas, such as a fluorine gas or an ozone gas. In all the experimental results, it was found that the cleaning rate tends to be improved by raising the temperature of the member on which the polymers are stacked.

### [Film Forming Method]

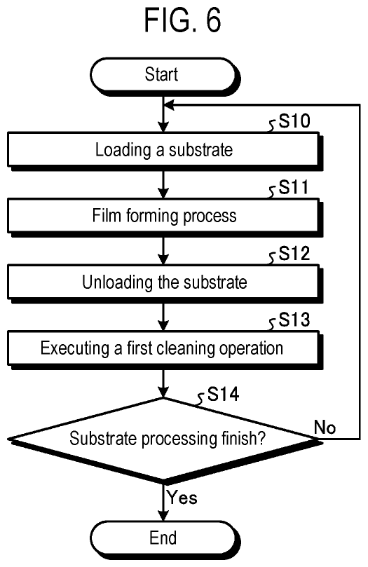

FIG. 6 is a flowchart showing an example of a film forming method. Each process shown in FIG. 6 is realized by controlling each part of the apparatus main body 200 with the control device 100.

First, the substrate is carried into the processing container 209 (S10). In step S10, the support structure 210 is lowered by driving the elevating mechanism 240, and the gate valve G is opened. Then, the substrate W is loaded into the lower container 201 through the opening 205 and mounted on the stage 211. Then, the gate valve G is closed, and the support structure 210 is raised by driving the elevating mechanism 240.

Next, a film forming process is performed on the substrate W (S11). In step S11, the heater 214 heats the substrate W on the stage 211 to a predetermined temperature. Further, the heater 251 heats the porous member 250 to a predetermined temperature. Then, an inert gas such as a nitrogen gas or the like is supplied from the gas supply 220 into the processing space Sp via the shower head 230. Then, the gas in the processing space Sp is exhausted by the exhaust device 208 via the exhaust port 203. Then, an isocyanate gas and an amine gas are further supplied from the gas supply 220 into the processing space Sp via the shower head 230, and the pressure in the processing space Sp is adjusted to a predetermined pressure by the pressure regulation valve 207. As a result, a polymer film having a urea bond is formed on the surface of the substrate W mounted on the stage 211.

At this time, the isocyanate gas and the amine gas that did not contribute to the film formation are drawn into the porous member 250 to form polymers in the porous member 250. As a result, the isocyanate gas and the amine gas that did not contribute to the film formation hardly flow into the exhaust pipe 206, and the deposition of the polymers on the pressure regulation valve 207 and the exhaust device 208 is suppressed.

The main processing conditions in step S11 are as follows, for example.
Temperature of substrate W: 80 degrees C.
Temperature of porous member 250: 150 degrees C.
Pressure in processing container 209: 1 Torr
Flow rate of isocyanate gas: 10 sccm
Flow rate of amine gas: 10 sccm
Flow rate of inert gas (N₂ gas): 200 sccm
Film-forming time: 120 seconds

When a polymer film having a predetermined thickness is formed on the substrate W, the film forming process is stopped and the substrate is unloaded from the processing container 209 (S12). In step S10, the support structure 210 is lowered by driving the elevating mechanism 240, and the gate valve G is opened. Then, the substrate W is unloaded from the stage 211 through the opening 205.

Next, a first cleaning operation for cleaning the inside of the processing container 209 is executed (S13). In step S13, a cleaning gas is supplied from the gas supply 220 into the processing space Sp via the shower head 230, and the pressure in the processing space Sp is regulated to a predetermined pressure by the pressure regulation valve 207. Then, RF power is supplied from the RF power source 260 into the processing space Sp via the matcher 261. As a result, the cleaning gas is turned into plasma in the processing space Sp, and the polymers adhering to the lower surfaces of the shower head 230 and the insulating member 204, the side wall of the exhaust duct 202, the upper surface of the stage 211, and the like are cleaned by the active species contained in the plasma. In this cleaning operation, the polymers adhering to the lower surface of the shower head 230, and the like are decomposed by the active species contained in the plasma, are converted into a substance having no deposition property, and are exhausted through the exhaust duct 202 and the exhaust pipe 206.

At this time, the polymers formed on the surface and pores of the porous member 250 are also decomposed by the active species contained in the plasma, are converted into a substance having no deposition property, and are exhausted through the exhaust duct 202 and the exhaust pipe 206. If the polymers drawn into the porous member 250 are removed by the cleaning operation, the polymer drawing-in ability of the porous member 250 is restored. Therefore, it is not necessary to open the processing container 209 to the atmosphere, take out the porous member 250 from the processing container 209, and remove the polymers adhering to the porous member 250. It is also not necessary to replace the porous member 250 with a new porous member having no polymer adhering thereto. As a result, it is possible to shorten the downtime of the film forming apparatus 10 and to improve the throughput of the film forming process.

The main processing conditions in step S13 are as follows, for example.
Temperature of porous member 250: 150 degrees C.
Pressure in processing container 209: 5 Torr
Flow rate of cleaning gas (O₂ gas): 1000 sccm
Cleaning time: 10 seconds

Next, the control device 100 determines whether or not to finish the processing of the substrate W (S14). If the control device 100 determines that the processing of the substrate is not finished (S14: No), the processing shown in step S10 is executed again. On the other hand, if the control device 100 determines that the processing of the substrate is finished (S14: Yes), the control device 100 finishes the process shown in the flowchart.

The first embodiment has been described above. As described above, the film forming apparatus 10 according to the present embodiment includes the stage 211, the processing container 209, the gas supply 220, the porous member 250, and the heater 251. The substrate W is mounted on the stage 211. The processing container 209 accommodates the stage 211. The gas supply 220 supplies the gases containing two types of monomers into the processing container 209 to form a polymer film on the substrate W mounted on the stage 211. The porous member 250 is arranged radially outward from the processing space Sp, which is the space above the substrate W, to draw in the polymers formed by the gases containing two types of monomers exhausted from the processing container 209. The heater 251 heats the porous member 250 to a first temperature when the polymer film is formed on the substrate W. This makes it possible to prevent a deposit from adhering to the exhaust path.

Further, in the above-described embodiment, the porous member 250 is provided between the stage 211 in the processing container 209 and the exhaust port 203 formed in the processing container 209. As a result, the porous member 250 can efficiently draw in the polymers formed by the gases containing two types of monomers exhausted from the processing container 209.

Further, the film forming apparatus 10 according to the above-described embodiment further includes the RF power source 260. The gas supply 220 supplies a cleaning gas into the processing container 209 when the substrate W is not mounted on the stage 211. The RF power source 260 converts the cleaning gas into plasma by supplying RF power into the processing container 209 when the substrate W is not mounted on the stage 211. The film of the polymers drawn into the porous member 250 is removed by the active species contained in the plasma. As a result, it is possible to efficiently remove the film of the polymers drawn into the porous member 250.

Further, in the above-described embodiment, the cleaning gas is a gas having molecules containing oxygen atoms or fluorine atoms. As a result, it is possible to efficiently remove the film of the polymers drawn into the porous member 250.

Further, in the above-described embodiment, during the film forming process, the porous member 250 is heated to a temperature at which the adsorption time of the monomers is in the range of, for example, 0.00001 ms or more and 0.01 ms or less. For example, during the film forming process, the porous member 250 is heated so that the temperature of the porous member 250 is in the range of 130 degrees C. to 170 degrees C. As a result, the pores on the surface of the porous member 250 are not blocked by the polymers, and the polymers reach the pores inside the porous member 250, whereby the polymers are drawn into the entire porous member 250. Therefore, it is possible to improve the polymer absorption capacity of the porous member 250 and to efficiently draw the polymers into the porous member 250.

Further, in the above-described embodiment, the surface area of the porous member 250 is 50,000,000 cm² or more. As a result, while the polymer film is formed on one substrate W, the polymers can be continuously drawn into the porous member 250 without saturating the polymer drawing-in effect obtained by the porous member 250. Therefore, it is possible to prevent a deposit from adhering to the exhaust path.

Further, in the above-described embodiment, the gas supply 220 supplies the amine gas and the isocyanate gas as the gases containing two types of monomers into the processing container 209, thereby forming a polymer film having urea bonds on the substrate W mounted on the stage 211. During the film forming process, the exhaust gas contains two types of monomers that did not contribute to the formation of the polymer film on the substrate W. By drawing the monomers into the porous member 250, it is possible to prevent a deposit from adhering to the exhaust path.

In order to sufficiently remove the polymers drawn into the pores of the porous member 250 in the cleaning operation, it is necessary to carry out the cleaning operation for a long time. However, if the cleaning operation is executed for a long time each time when the film forming process for one substrate W is completed, it becomes difficult to improve the overall throughput of the film forming process for a plurality of substrates W. Therefore, when the film forming process on one substrate W is completed, a cleaning operation for a short time may be performed to remove the polymers drawn into the pores of the porous member 250 to the extent that the polymer drawing-in effect obtained by the porous member 250 is not saturated during the film forming process on one substrate W.

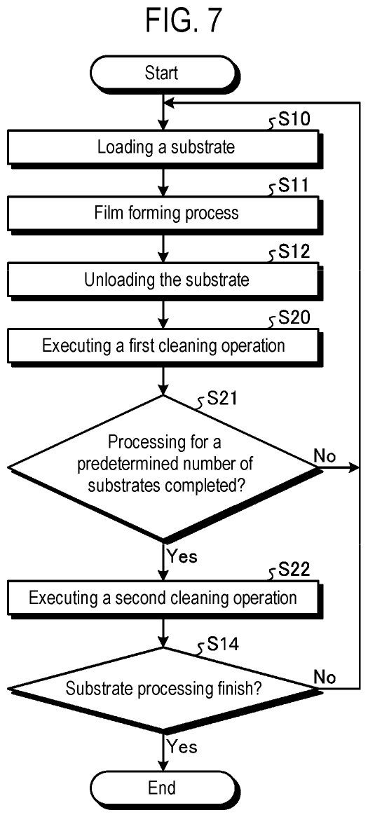

However, in that case, the polymers that could not be completely removed may accumulate in the pores of the porous member 250. Therefore, for example, as shown in FIG. 7, it is preferable that each time when the film forming process for a plurality of substrates W is completed, a long-time cleaning operation is performed to sufficiently remove the polymers drawn into the pores of the porous member 250. FIG. 7 is a flowchart showing another example of the film forming method. Except for the points described below, in FIG. 7, the processes designated by the same reference numerals as those in FIG. 6 are the same as the processes described with reference to FIG. 6. Therefore, the duplicate description thereof will be omitted.

After the substrate W is unloaded in step S12, a first cleaning operation for cleaning the inside of the processing container 209 is executed (S20). The cleaning time in step S20 is a time, for example, 10 seconds, required for removing the polymer drawn into the pores of the porous member 250 to the extent that the polymer drawing-in effect obtained by the porous member 250 is not saturated during the film forming process on one substrate W. The conditions other than the cleaning time in step S20 are the same as the conditions in step S13 shown in FIG. 6.

Next, the control device 100 determines whether or not the film forming process for a predetermined number of substrates W has been completed (S21). When the control device 100 determines that the film forming process for the predetermined number of substrates W has not been completed yet (S21: No), the processes shown in step S10 is executed again.

On the other hand, when the control device 100 determines that the film forming process for the predetermined number of substrates W has been completed (S21: Yes), a second cleaning operation is executed (S22). The cleaning time in step S22 is longer than the cleaning time in step S20. The cleaning time in step S22 is a time, for example, 600 seconds, required for sufficiently removing the polymers drawn into the pores of the porous member 250. The conditions other than the cleaning time in step S22 are the same as the conditions in step S13 shown in FIG. 6. Then, the process shown in step S14 is executed. This makes it possible to improve the overall throughput of the film forming process for the plurality of substrates W.

### Second Embodiment

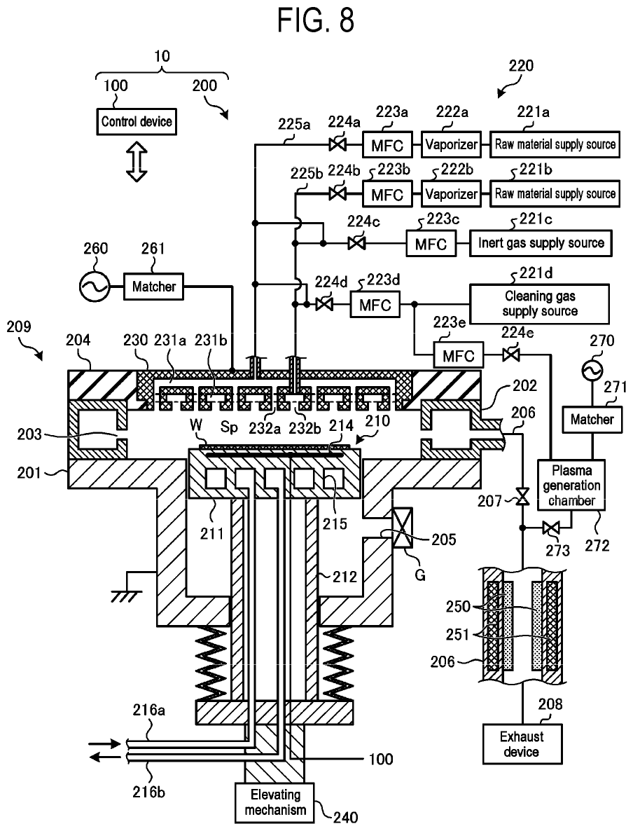

In the above-described embodiment, the porous member 250 is provided inside the processing container 209. However, the disclosed technique is not limited thereto, and the porous member 250 may be provided in the exhaust pipe 206, for example, as shown in FIG. 8. FIG. 8 is a schematic sectional view showing an example of a film forming apparatus 10 according to a second embodiment. Except for the points described below, in FIG. 8, the configurations designated by the same reference numerals as those in FIG. 1 have the same or similar functions as the configurations shown in FIG. 1. Therefore, the description thereof will be omitted.

In the present embodiment, the porous member 250 and the heater 251 are provided on the side wall of the exhaust pipe 206. The heater 251 heats the porous member 250 to a temperature at which the adsorption time of monomers is in the range of, for example, 0.00001 ms or more and 0.01 ms or less while the film forming process on the substrate W is being executed. For example, the heater 251 heats the porous member 250 to a temperature in the range of 130 degrees C. to 170 degrees C.

The gas exhausted from the processing container 209 flows through the exhaust pipe 206 and passes through the porous member 250. At that time, the polymer film formed by the monomers contained in the exhaust gas is drawn into the pores of the porous member 250. This suppresses the formation of a polymer film on the downstream side of the position of the exhaust pipe 206 at which the porous member 250 is arranged.

A plasma generation chamber 272 is connected to the exhaust pipe 206 between the portion of the exhaust pipe 206, at which the porous member 250 is provided, and the pressure regulation valve 207 via a pipe. A valve 273 is provided in the pipe. The plasma generation chamber 272 is an example of a second container. An RF power source 270 is electrically connected to the plasma generation chamber 272 via a matcher 271. Further, a cleaning gas supply source 221d is connected to the plasma generation chamber 272 via a pipe. An MFC 223e and a valve 224e are provided in the pipe.

In the present embodiment, the cleaning for the inside of the processing container 209 and the cleaning for the porous member 250 provided in the exhaust pipe 206 are performed independently of each other. When the cleaning for the porous member 250 provided in the exhaust pipe 206 is executed, the valves 224e and 273 are opened to supply a cleaning gas into the plasma generation chamber 272 at a predetermined flow rate under the control of the MFC 223e. Then, the pressure in the plasma generation chamber 272 is regulated under the control of the valve 273. Then, RF power is supplied from the RF power source 270 into the plasma generation chamber 272 via the matcher 271. As a result, the cleaning gas in the plasma generation chamber 272 is turned into plasma, and the active species contained in the plasma are supplied to the porous member 250 in the exhaust pipe 206 via the valve 273.

The main processing conditions for cleaning the porous member 250 in the exhaust pipe 206 are as follows, for example.
Temperature of porous member 250: 150 degrees C.
Pressure in plasma generation chamber 272: 5 Torr
Flow rate of cleaning gas (O₂ gas): 1000 sccm
Cleaning time: 10 seconds

As a result, the polymers formed on the surface and pores of the porous member 250 are decomposed by the active species contained in the plasma, are converted into a substance having no deposition property, and are discharged to the downstream side of the exhaust pipe 206 at which the porous member 250 is arranged. Therefore, also in this embodiment, it is possible to prevent a deposit from adhering to the exhaust path.

### [Others]

The technique disclosed in the subject application is not limited to the above-described embodiments, and many modifications can be made within the scope of the gist thereof.

For example, in each of the above-described embodiments, the heater 251 heats the porous member 250 to the same temperature both during the film forming process for the substrate W and during the cleaning for the porous member 250. However, the disclosed technique is not limited thereto. For example, the heater 251 may heat the porous member 250 to a first temperature during the film forming process for the substrate W, and the heater 251 may heat the porous member 250 to a second temperature higher than the first temperature during the cleaning for the porous member 250. The first temperature is a temperature at which the adsorption time of monomers is in the range of, for example, 0.00001 ms or more and 0.01 ms or less. For example, the first temperature is a temperature in the range of 130 degrees C. to 170 degrees C. The second temperature is, for example, a temperature of 300 degrees C. or higher.

By heating the porous member 250 to the second temperature higher than the first temperature during the cleaning of the porous member 250, the depolymerization of the polymers formed in the pores of the porous member 250 is promoted, and the monomers are likely to be discharged from the porous member 250. As a result, the active species contained in the plasma and the monomers can react more efficiently, and the porous member 250 can be efficiently cleaned.

Further, in each of the above-described embodiments, the porous member 250 is cleaned using plasma. However, the disclosed technique is not limited thereto. For example, even in the experiment 4 using a fluorine gas and the experiment 5 using an ozone gas, which are shown in FIG. 5, the porous member 250 can be cleaned. Therefore, even when plasma is not used, the porous member 250 may be cleaned by using a gas having a higher reactivity than the oxygen gas, such as a fluorine gas or an ozone gas.

Further, in the first embodiment described above, the porous member 250 is provided in the processing container 209, and in the second embodiment described above, the porous member 250 is provided in the exhaust pipe 206. However, the disclosed technique is not limited thereto. The porous member 250 may be provided both in the processing container 209 and in the exhaust pipe 206. That is, the first embodiment and the second embodiment may be combined.

Further, in the above-described embodiments, the polymers having a urea bond are used as an example of the polymers formed by the polymerization of two types of monomers. However, polymers having a bond other than the urea bond may be used as the polymers formed by the polymerization of two types of monomers. Examples of the polymers having a bond other than the urea bond include polyurethane having a urethane bond. Polyurethane can be synthesized, for example, by copolymerizing a monomer having an alcohol group and a monomer having an isocyanate group. Further, polyurethane can be depolymerized into a monomer having an alcohol group and a monomer having an isocyanate group by being heated to a predetermined temperature.

It should be noted that the embodiments disclosed herein are exemplary and are not limitative in all respects. Indeed, the above-described embodiments may be embodied in a variety of forms. Moreover, the above-described embodiments may be omitted, replaced, or changed in various forms without departing from the scope of the appended claims and the purpose thereof.

According to the present disclosure in some embodiments, it is possible to prevent a deposit from adhering to an exhaust path.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus, comprising:
a stage on which a substrate is mounted;
a first container configured to accommodate the stage;
a gas supply configured to supply gases containing two types of monomers into the first container to form a polymer film on the substrate mounted on the stage;
a porous member arranged radially outward from a processing space, which is a space above the substrate, and configured to draw in polymers formed by the gases containing two types of monomers exhausted from the first container; and
a heater configured to heat the porous member to a first temperature when the polymer film is formed on the substrate.

2. The apparatus of claim 1, wherein the porous member is provided between the stage in the first container and an exhaust port formed in the first container.

3. The apparatus of claim 2, wherein the gas supply is configured to supply a cleaning gas into the first container when the substrate is not mounted on the stage, the apparatus further comprising:
an RF power source configured to, when the substrate is not mounted on the stage, supply RF (Radio Frequency) power into the first container to turn the cleaning gas into plasma and remove the polymer film drawn into the porous member by active species contained in the plasma.

4. The apparatus of claim 3, wherein the cleaning gas is a gas having molecules containing oxygen atoms or fluorine atoms.

5. The apparatus of claim 4, wherein the heater is configured to heat the porous member to a second temperature higher than the first temperature while the cleaning gas is being supplied.

6. The apparatus of claim 5, wherein the first temperature is a temperature at which an adsorption time of the monomers is in a range of 0.00001 ms or more and 0.01 ms or less.

7. The apparatus of claim 6, wherein s surface area of the porous member is 50,000,000 cm² or more.

8. The apparatus of claim 7, wherein the gas supply is configured to supply an amine gas and an isocyanate gas as the gases containing two types of monomers into the first container to thereby form the polymer film having a urea bond on the substrate mounted on the stage.

9. The apparatus of claim 1, wherein the porous member is provided in an exhaust pipe for exhausting gases in the first container.

10. The apparatus of claim 9, wherein the gas supply is configured to supply a cleaning gas into a second container that generates plasma for supplying active species into the exhaust pipe in which the porous member is provided, the apparatus further comprising:
an RF power source configured to supply RF power into the second container to turn the cleaning gas into plasma and supply the active species contained in the plasma into the exhaust pipe in which the porous member is provided, so that the polymer film drawn into the porous member is removed by the active species.

11. The apparatus of claim 3, wherein the heater is configured to heat the porous member to a second temperature higher than the first temperature while the cleaning gas is being supplied.

12. The apparatus of claim 1, wherein the first temperature is a temperature at which an adsorption time of the monomers is in a range of 0.00001 ms or more and 0.01 ms or less.

13. The apparatus of claim 1, wherein the first temperature is a temperature in a range of 130 degrees C. to 170 degrees C.

14. The apparatus of claim 1, wherein a surface area of the porous member is 50,000,000 cm² or more.

15. The apparatus of claim 1, wherein the gas supply is configured to supply an amine gas and an isocyanate gas as the gases containing two types of monomers into the first container to thereby form the polymer film having a urea bond on the substrate mounted on the stage.
